(19) United States
(12) Patent Application Publication
(10) Pub. No.: US 2008/0153241 A1
(43) Pub. Date: Jun. 26, 2008

(54) METHOD FOR FORMING FULLY SILICIDED GATES

(76) Inventors: Chia-Jung Hsu, Changhua County (TW); Chin-Hsiang Lin, Hsin-Chu City (TW); Li-Wei Cheng, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/616,029

(22) Filed: Dec. 26, 2006

(51) Int. Cl. H01L 21/336; H01L 21/28

(52) U.S. Cl. 438/305; 438/586; 257/E21.409; 257/E21.177

(57) ABSTRACT

A method for forming a fully silicided gate is disclosed. A gate structure of a transistor device is provided on a substrate. A mask layer is spin-on coated over the substrate to cover the gate structure and source/drain regions of the transistor device. The mask layer is etched back to expose a silicon layer of the gate structure. The silicon layer of the gate structure is then fully silicided. The mask layer is then removed from the substrate to expose the source/drain regions. The source/drain regions are finally silicided.

### BACKGROUND OF THE INVENTION

1. Field of the Invention

The present invention relates generally to semiconductor processing. More specifically, the present invention relates to a method for forming fully silicided gate electrodes in a semiconductor device.

2. Description of the Prior Art

As semiconductor technology advances, semiconductor devices are becoming increasingly smaller. However, this scaling down of devices may cause problems. For example, as gate oxides are scaled down, gate capacitance due to polysilicon depletion issues becomes more problematic, adversely affecting device performance. Therefore, one solution to this problem is the use of different metal gates for both NMOS and PMOS field effect transistors to serve as a replacement to polysilicon gates. However, the formation and integration of these dual metal gates are complex tasks as compared to form traditional doped polysilicon gates.

Therefore, instead of the formation of dual metal gates, one type of technology known today is to form a fully silicided gate electrode by using radiated heat during a rapid thermal annealing process to fully silicide a silicon layer.

Silicides are typically formed by reacting a metal with crystallized silicon (Si) within a specified temperature range and time. Silicide layers may be self-aligned by different techniques. For example, selectively depositing the metal on the top of the gate electrode and on the source/drain regions of a semiconductor device prior to an annealing process causes only partial Si of the source/drain regions and the gate electrode to form silicides upon annealing.

Alternatively, sidewall spacers on the sides of the gate electrode comprising of a material that does not react with the metal layer allow a blanket layer of metal to be deposited over a semiconductor device while restricting silicide formation to a portion of the exposed source/drain regions during an annealing process.

During the annealing process, the semiconductor device is heated to a reaction temperature, and held at the reaction temperature for a period of time, causing the metal layer to react with the crystallized Si that the metal contacts, and thus forming a silicide layer on the residual crystallized Si substrate of the source/drain regions and/or the gate electrode.

However, the simultaneous formation of silicide on the gate electrode and the source/drain regions leads to the risk of spiking in the source/drain regions, while completing silicidation of the gate electrode is attempted. The exposure of the metal and silicon under rapid thermal annealing conditions is sufficient to completely silicide a gate electrode may cause the silicide to spike and reach the bottom of a junction so that the undesirable current leakage is caused.

One approach to the formation of the fully silicided gate electrode includes the steps of forming a known self-aligned silicide with the gate electrode that is partly silicided, depositing dielectric layers to cover the partial silicided gate electrode and the silicided source/drain regions next to the gate electrode, then implement the chemical mechanical polishing (CMP) process to remove the dielectric layer until the partial silicided gate electrode is exposed, or remove the dielectric layer and partial silicided layer until the unreacted gate electrode is exposed, and then fully siliciding the gate electrode. One drawback of the aforesaid approach is that the CMP process causes within-wafer thickness variation of remaining gate height due to the non-uniformity of the polishing process. It is desired to accurately control the remaining gate height of each transistor device for the sake of complete silicidation. Moreover, the high thermal budget to fully silicide the gate electrode also adversely affects the junction depth and performance of the silicided source/drain regions.

U.S. Pat. No. 6,905,922 to Lin, et al. filed Oct. 3, 2003 discloses a semiconductor device having a plurality of silicidation steps. However, the method of U.S. Pat. No. 6,905,922 is complex because it involves multiple patterning steps, thus is not cost-effective.

Therefore, a need exists for an improved method for forming fully silicided gates, which allows for improved manufacturability and yield.

### SUMMARY OF THE INVENTION

It is one object of the present invention to provide an improved method for forming fully silicided gates in order to solve the above-mentioned problems.

According to the claimed invention, a method for forming a fully silicided gate is disclosed. The method starts with providing a gate structure of a transistor device on a substrate. A mask layer is formed over the substrate to cover the gate structure and source/drain regions of the transistor device. The mask layer is partially removed to expose a gate electrode layer of the gate structure. The gate electrode layer of the gate structure is then fully silicided. The mask layer is then removed from the substrate to expose the source/drain regions. The source/drain regions are finally silicided.

From one aspect of this invention, a method of forming a fully silicided gate is disclosed. A gate structure of a transistor device is provided on a substrate. A mask layer is formed on the substrate to cover the gate structure and source/drain regions of the transistor device. The mask layer is partially removed to expose a gate electrode layer of the gate structure. The gate electrode layer of the gate structure is partially silicided. The remaining mask layer is removed from the substrate to expose the source/drain regions. The source/drain regions are silicided and, simultaneously, the remaining gate electrode layer of the gate structure is fully silicided.

From another aspect of this invention, a method for forming a semiconductor device is disclosed. A gate structure of a transistor device is formed on a substrate. A mask layer is formed on the substrate to cover the gate structure and source/drain regions of the transistor device. The mask layer is partially removed to expose a gate electrode layer of the gate structure. A first metal is blanket deposited over the substrate to cover the gate structure and source/drain regions. The gate electrode layer of the gate structure is then silicidized by reacting the first metal with the gate electrode layer. The unreacted metal is removed by chemical solution. The remaining mask layer is removed from the substrate to expose the source/drain regions. A second metal is then blanket deposited over the substrate to cover the gate structure and source/drain regions. The source/drain regions are silicided by reacting the second metal.

It is advantageous to use the present invention because the gate is fully silicided prior to the silicidation of source/drain regions. In one embodiment, the gate is first partially silicided and then completely fully silicided combined with the silicidation of source/drain regions. By doing this, the higher thermal budget then conventional silicide formation used for forming the fully silicided gate will not adversely affect the source/drain junction performance. The yield and device performance are thus improved.

From another aspect of this invention, a dual-gate silicide process is disclosed. A substrate having thereon a first gate structure and a second gate structure is provided. A dielectric layer is deposited to cover the first gate structure and the second gate structure. A first opening is defined in the dielectric layer to expose a top surface of the first gate structure by etching. A first metal layer is deposited on the dielectric layer and filled into the first opening. The first gate structure is then transformed into a high-temperature Si-rich phase gate. The unreacted portion of the first metal layer is removed. A portion of the dielectric layer is etched away to expose a top surface of the second gate structure. A second metal layer is deposited to cover the high-temperature Si-rich phase gate, the dielectric layer and the exposed top surface of the second gate structure. The second gate structure is then transformed into a low-temperature Ni-rich phase gate. The unreacted portion of the second metal layer is removed. The remanent portion of the dielectric layer is removed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-9 are schematic, cross-sectional diagrams illustrating the method for forming fully silicided gate electrode of a metal-oxide-semiconductor (MOS) transistor device in accordance with one preferred embodiment of this invention;

FIGS. 10-18 are schematic, cross-sectional diagrams illustrating the method for forming fully silicided gate electrode of a metal-oxide-semiconductor (MOS) transistor device in accordance with another preferred embodiment of this invention;

FIG. 19 is a flow chart in accordance with the preferred embodiment of this invention; and

FIGS. 20-31 are schematic diagrams illustrating a dual-gate silicide process in accordance with another preferred embodiment of this invention.

### DETAILED DESCRIPTION

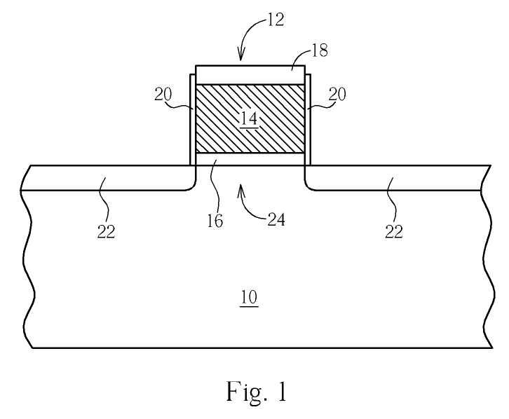

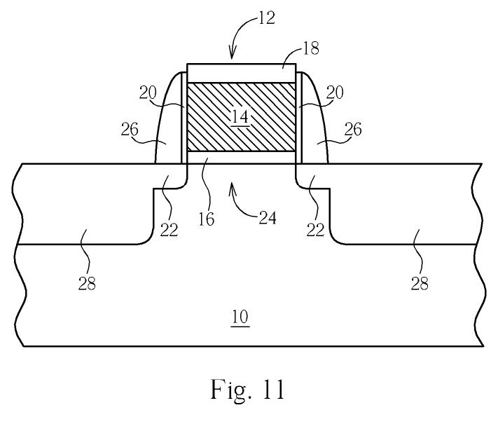

In describing the preferred embodiments of the present invention, reference will be made herein to FIGS. 1-31 of the drawings. Features of the invention are not drawn to scale in the drawings. It is to be understood that some lithographic, ion implanting and etching processes relating to the present invention method are known in the art and thus not explicitly shown in the drawings.

Please refer to FIGS. 1-9. FIGS. 1-9 are schematic, cross-sectional diagrams illustrating the method for forming fully silicided gate electrode of a metal-oxide-semiconductor (MOS) transistor device in accordance with one preferred embodiment of this invention. It is noted that this invention is applicable to both NMOS and PMOS processes.

As shown in FIG. 1, a semiconductor substrate 10 is provided. According to this invention, the semiconductor substrate 10 may be a silicon substrate or a silicon-on-insulator (SOI) substrate, but not limited thereto. Preferably, the semiconductor substrate 10 is silicon based, (e.g., silicon, silicon alloy or a combination thereof including Si, SiGe, SiC, SiGeC) although any suitable semiconductor material may be used including, but not limited to GaAs, InAs, InP or other III/V compound semiconductors. The semiconductor substrate 10 may also include a multilayer structure in which at least the top layer thereof is a semiconductor.

A gate structure 12 is formed on a main surface of the semiconductor substrate 10. The gate structure 12 comprises a gate electrode layer 14 such as polycrystalline silicon, a gate dielectric layer 16 interposed between the semiconductor substrate 10 and the gate electrode layer 14, and a cap layer 18 atop the gate electrode layer 14. Optionally, an offset oxide spacer 20 is formed on opposite sidewalls of the gate structure 12. Shallow junction source/drain extensions 22 of the same conductivity type are formed in the semiconductor substrate 10 adjacent to the gate structure 12.

The method for forming the intermediate MOS structure depicted in FIG. 1 generally comprises forming shallow trench isolation (STI) structure (not shown) in the substrate; forming gate dielectric layer 16; depositing a gate electrode layer 14 over the gate dielectric layer 16; depositing a cap layer 18 over the gate electrode layer 14; patterning the cap layer 18, the gate electrode layer 14, and the gate dielectric layer 16 to form gate structure 12; forming liner 20; and ion implanting shallow junction source/drain extensions 22 into the substrate using the gate structure 12 as a hard mask. A channel 24 is defined between the source/drain extensions 22 directly underneath the gate structure 12.

The gate electrode layer 14 comprises polycrystalline Si and amorphous Si; doped and un-doped impurities. The impurities may contain boron, phosphorus, and boron compound such as BF2+.

The gate dielectric layer 16 is formed on the main surface of the semiconductor substrate 10 using a suitable formation step, for example, depositing or thermal growing the dielectric, followed by nitridation or oxynitridation treatment. Combinations of the aforementioned processes may also be used in forming the gate dielectric layer 16. The gate dielectric layer 16 may comprise insulating material including an oxide, nitride, oxynitride or any combination thereof. A highly preferred insulating material that may be employed in the present invention as the gate dielectric is nitrided SiO₂ or oxynitride.

Although it is preferred to use nitrided SiO₂ or oxynitride as the gate dielectric material, the present invention also contemplates using insulating materials, i.e., dielectrics, which have a higher dielectric constant, k, than nitrided SiO₂. For example, the high k dielectric material is formed by a chemical vapor deposition (CVD), metal-organic CVD (MOCVD), or atomic layer CVD (ALD) process. The high k dielectric material is selected from a group of metal oxides including Ta2O5, TiO2, Al2O3, ZrO2, HfO2, Y2O3, L2O3 and their aluminates and silicates. The high k dielectric materials also comprise the above metal oxides including Ta2O5, TiO2, Al2O3, ZrO2, HfO2, Y2O3, L2O3 and nitrogen incorporated in their aluminates and silicates such as HfSiON. The high k dielectric material may comprise a single layer of one metal oxide or several layers including two or more metal oxides. Prior to the high k dielectric materials formation, an interfacial layer (IL) comprised of SiON, Si3N4 or SiO2 is formed between high k and the substrate. The IL layer could be formed by chemical oxidation of the substrate by ozone, or by oxygen plasma oxidation substrate, or by rapid thermally grown oxide (RPO). Prior to the IL formation, a pre-gate cleaning step, which is suitable for high-k deposition, can be inserted before the high k dielectric stack deposition. Such a cleaning step typically involves a hydrophilic or hydrophobic technique that is well known to those skilled in the art.

Preferably, the cap layer 18 is made of silicon oxide or silicon oxy-nitride, nitride or combined stack. Nevertheless, the cap layer 18 may be made of any other suitable material such as silicon carbide. It should be understood that, in some cases, the cap layer 18 is omitted.

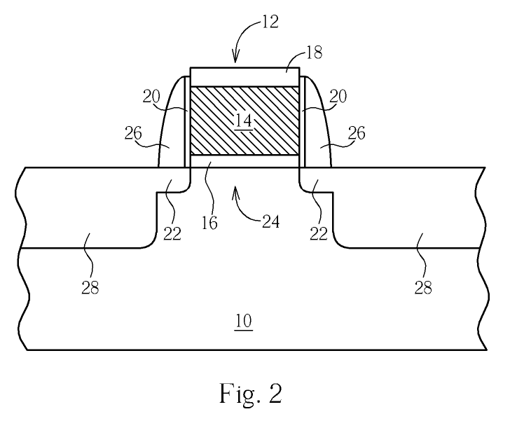

As shown in FIG. 2, silicon nitride spacers 26 are formed on respective sidewalls of the gate structure 12. A thin liner (not shown) such as silicon dioxide liner may be provided between the silicon nitride spacer 26 and the gate structure 12. Typically, the liner is L-shaped and has a thickness of about 30-120 angstroms.

The method of forming the silicon nitride spacers 26 generally includes the steps of depositing a conformal silicon nitride layer (not shown) on the silicon oxide liner; dry etching back the silicon nitride layer to form the silicon nitride spacers on sidewalls of the gate structure 12. According to the preferred embodiment of this invention, the thickness of the silicon nitride spacer 26 is between 300-1000 angstroms. In other cases, the silicon nitride spacer 26 may be replaced with other suitable materials including, but not limited to, silicon oxy-nitride (SiON), oxide-nitride-oxide (ONO), nitride-oxide (NO) or silicon carbide (SiC).

Using the silicon nitride spacers 26 and the gate structure 12 as an implant mask, a conventional ion implantation process is carried out to dope species such as boron, boron compound, arsenic, antimony, germanium or phosphorous into the semiconductor substrate 10, thereby forming heavily doped implantation in source/drain regions 28 that are contiguous with the shallow junction source/drain extensions 22.

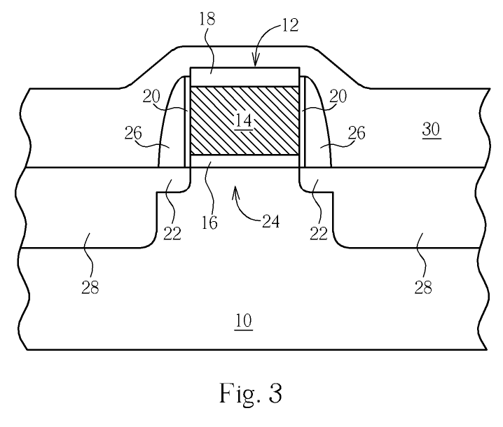

As shown in FIG. 3, after the source/drain implantation, a mask layer layer 30 is formed over the semiconductor substrate 10. The mask layer 30 maybe spin-on glass (SOG), spin-on dielectric (SOD), wherein the mask layer 30 maybe silicon dioxide and silicon oxynitride formed by plasma enhanced(PE) CVD, low-pressure(LP) CVD, sub-atmosphere (SA) CVD or atmosphere (AP) CVD. Optionally, prior to the formation of the mask layer 30, a dielectric liner layer (not shown) including, but not limited to, silicon dioxide, silicon oxynitride, may be deposited over the semiconductor substrate 10. It is advantageous to add this dielectric liner layer because it is capable of blocking moisture.

The mask layer 30 includes, but not limited to, silicon dioxide, silicon oxynitride, spin-on polymers, spin-on photoresist materials, siloxene, polyimide (PI), benzocyclobutene (BCB), and low-k materials such as SiLK® (Trademark of Dow Chemical Company), Hydrogen Silisequioxane (HSQ) or FOx® (Trademark of Dow Corning). The mask layer 30 covers the gate structure 12, the silicon nitride spacers 26 and source/drain regions 28.

According to the preferred embodiment of this invention, the mask layer 30 is thinner at the top of the gate structure 12 than that at the top of the source/drain regions 28. Preferably, the thickness of the mask layer 30 that is directly above the gate structure 12 ranges between 500 angstroms and 50 angstroms. The thickness of the mask layer 30 above the source/drain regions 28 preferably ranges between 500 angstroms and 1500 angstroms.

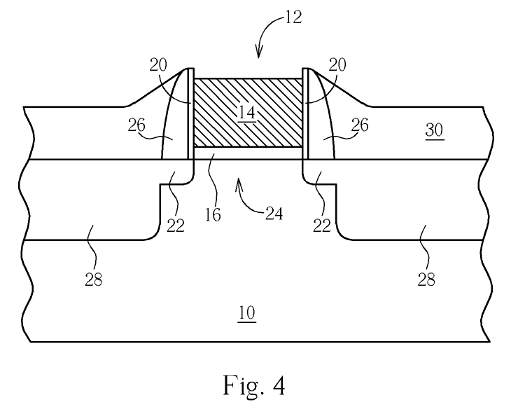

Subsequently, as shown in FIG. 4, the mask layer 30 and the cap layer 18 are removed to expose the gate electrode layer 14 of the gate structure 12. The mask layer 30 and the cap layer 18 may be removed by employing conventional wet etching methods or dry etching methods. The wet etching preferred comprises HF and diluted HF wherein the dry etching preferred comprises carbon, fluorine and compound. Thereafter, the remaining thickness of the mask layer 30 above the source/drain regions 28 is preferably greater than 200 angstroms, more preferably, greater than 500 angstroms.

Another embodiment of this invention, the mask layer 30 is formed at the top of the gate structure 12 and at the top of the source/drain regions 28. The mask layer 30 are partially removed away to leave portion of the mask layer 30 on top of the gate electrode layer 14 and on top of the gate structure 12. The mask layer 30 may be partially removed by employing planarization method such as but not limited to CMP. It is noticed that herein the CMP process is quite difference from the prior art application. In this invention, the CMP is utilized to remove portion of the dielectric layer only and won't touch gate electrode layer. Subsequently, the mask layer 30 and the cap layer 18 may be removed by employing conventional wet etching methods or dry etching methods to expose the gate electrode layer 14 of the gate structure 12. After removing, the remaining thickness of the mask layer 30 above the source/drain regions 28 is preferably greater than 200 angstroms, more preferably, greater than 500 angstroms.

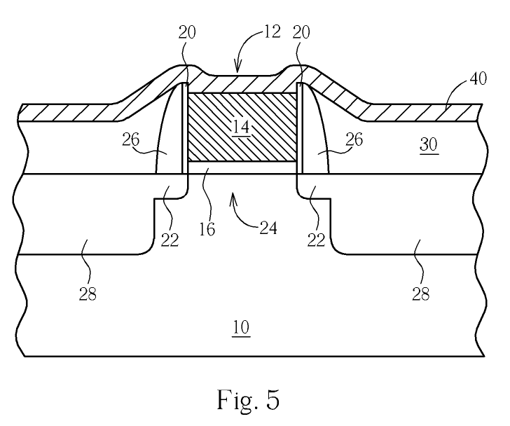

As shown in FIG. 5, a metal layer 40, such as nickel, cobalt, titanium, or any suitable materials for silicide is blanket deposited over the semiconductor device including the exposed surface of the gate structure 12. The formation of metal layer 40 can be effected in any conventional manner, such as chemical vapor deposition (CVD) or sputtering. An exemplary thickness of metal layer 40 is between about 80 angstroms and about 150 angstroms. The thickness of the deposited metal layer 40 is at least of a specific thickness that, during subsequent annealing, will react with the gate electrode, to silicide the gate electrode layer 14. However, for fully silicided gate application, the thickness of the metal is variable to the height of the gate electrode layer 14. The thickness of the gate electrode layer 14 may range between 500 and 1500 angstroms. Hence, the thickness of the metal layer 40 is preferably between 300 and 2500 angstroms to assure that the gate is fully silicided.

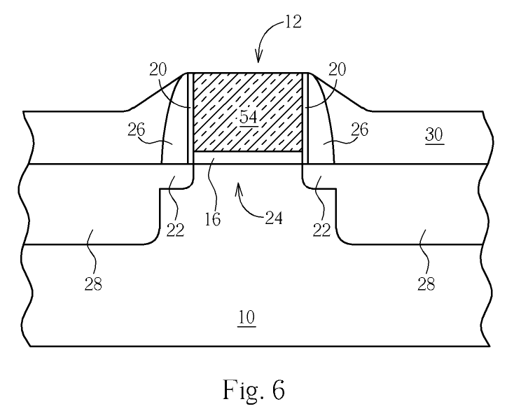

As shown in FIG. 6, a thermal annealing process is then carried out to fully silicide the gate electrode, thereby forming a fully silicided layer 54. The thermal annealing process may take place at a temperature of about 300° C. to about 900° C. for about 10 to about 600 seconds. Other parameters may be used depending on the metal used and the silicide qualities desired. Thereafter, the unreacted metal is removed from the mask layer 30 and from the gate electrode layer 14. The unreacted metal may be removed by a wet chemical etch, such as with sulfuric peroxide mixture H₂SO₄:H₂O₂ (3:1) with deionized H₂O at a temperature of 100° C.

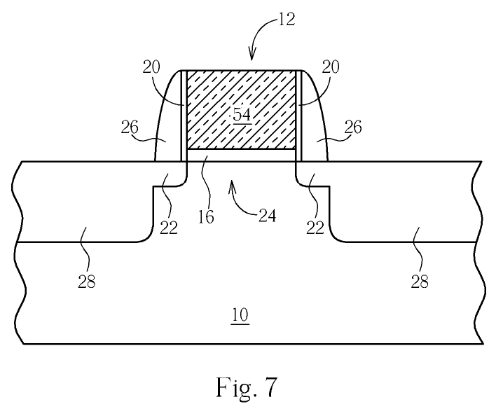

As shown in FIG. 7, after removing the unreacted metal, the mask layer 30 is removed from the semiconductor substrate 10 to expose the source/drain regions 28. Likewise, the mask layer 30 may be removed by employing conventional wet etching methods or dry etching methods.

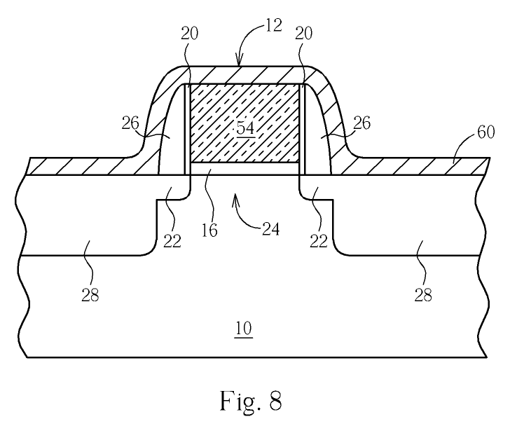

As shown in FIG. 8, another metal layer 60 is blanket deposited over the semiconductor substrate 10 including the exposed surface of the fully silicided layer 54 and the surface of the nitride spacers 26. The metal layer 60 and the metal layer 40 may be of the same metal such as nickel. Alternatively, the metal layer 60 and the metal layer 40 may be composed of different metals, for example, the metal layer 60 is titanium or cobalt, while the metal layer 40 is nickel. The metal layer 60 contacts the source/drain regions 28.

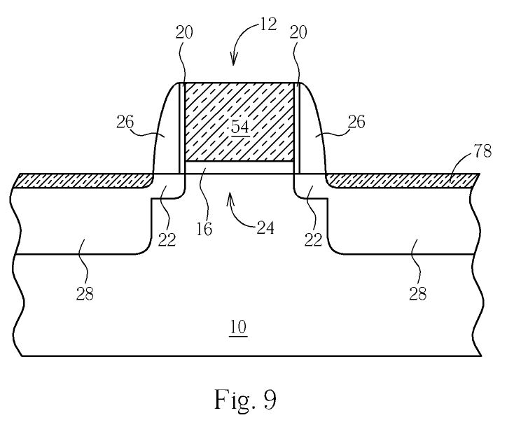

As shown in FIG. 9, another thermal annealing process is carried out. The thermal annealing process may take place at a temperature of about 300° C. to about 900° C. for about 10 to about 300 seconds. Other parameters may be used depending on the metal used and the silicide qualities desired. Upon annealing, a silicide layer 78 forms in the source/drain regions 28. Thereafter, the unreacted metal is removed from the substrate 10. In some other embodiments, after removing the unreacted metal, a second thermal annealing process is carried out. The second thermal annealing process may be implemented at a temperature of about 300° C. to about 900° C. for about 10 to about 300 seconds.

It is advantageous to use the present invention because the gate is fully silicided prior to the silicidation of source/drain region 28. By doing this, the inevitable high thermal budget used for forming the fully silicided gate will not adversely affect the source/drain junction performance. The yield and device performance are thus improved.

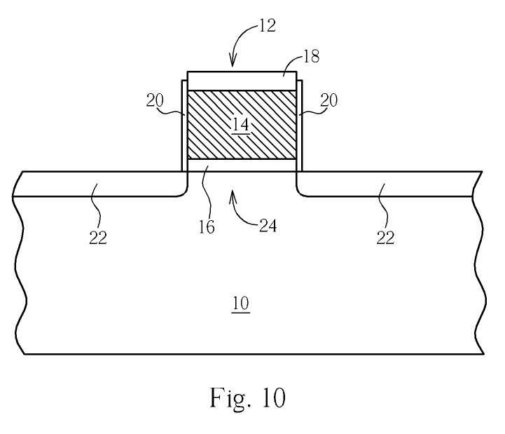

Please refer to FIGS. 10-18. FIGS. 10-18 are schematic, cross-sectional diagrams illustrating the method for forming fully silicided gate electrode of a metal-oxide-semiconductor (MOS) transistor device in accordance with another preferred embodiment of this invention, wherein like numeral numbers designate like devices, layers or elements.

As shown in FIG. 10, a semiconductor substrate 10 is provided. According to this invention, the semiconductor substrate 10 may be a silicon substrate or a silicon-on-insulator (SOI) substrate, but not limited thereto. Preferably, the semiconductor substrate 10 is silicon based, (e.g., silicon, silicon alloy or a combination thereof including Si, SiGe, SiC, SiGeC) although any suitable semiconductor material may be used including, but not limited to GaAs, InAs, InP or other III/V compound semiconductors. The semiconductor substrate 10 may also include a multilayer structure in which at least the top layer thereof is a semiconductor.

A gate structure 12 is formed on a main surface of the semiconductor substrate 10. The gate structure 12 comprises a gate electrode layer 14, a gate dielectric layer 16 interposed between the semiconductor substrate 10 and the gate electrode layer 14, and a cap layer 18 atop the gate electrode layer 14. Optionally, an offset oxide spacer 20 is formed on opposite sidewalls of the gate structure 12. Shallow junction source/drain extensions 22 of the same conductivity type are formed in the semiconductor substrate 10 adjacent to the gate structure 12.

The method for forming the intermediate MOS structure depicted in FIG. 10 generally comprises forming shallow trench isolation (STI) structure (not shown) in the substrate; forming gate dielectric layer 16; depositing a gate electrode layer 14 over the gate dielectric layer 16; depositing a cap layer 18 over the gate electrode layer 14; patterning the cap layer 18, the gate electrode layer 14 and the gate dielectric layer 16 to form gate structure 12; forming liner 20; and ion implanting shallow junction source/drain extensions 22 into the substrate using the gate structure 12 as a hard mask. A channel 24 is defined between the source/drain extensions 22 directly underneath the gate structure 12.

The gate electrode layer 14 comprises polycrystalline Si and amorphous Si; doped and un-doped impurities. The impurities may contain boron, phosphorus, and boron compound such as BF2+.

The gate dielectric layer 16 is formed on the main surface of the semiconductor substrate 10 using a suitable formation step such as for example, depositing or thermal growing the dielectric, followed by nitridation or oxynitridation treatment. Combinations of the aforementioned processes may also be used in forming the gate dielectric layer 16. The gate dielectric layer 16 may comprise insulating material including an oxide, nitride, oxynitride or any combination thereof. A highly preferred insulating material that may be employed in the present invention as the gate dielectric is nitrided SiO₂ or oxynitride.

Although it is preferred to use nitrided SiO₂ or oxynitride as the gate dielectric material, the present invention also contemplates using insulating materials, i.e., dielectrics, which have a higher dielectric constant, k, than nitrided SiO₂. For example, the high k dielectric material is formed by a chemical vapor deposition (CVD), metal-organic CVD (MOCVD), or atomic layer CVD (ALD) process. The high k dielectric material is selected from a group of metal oxides including Ta2O5, TiO2, Al2O3, ZrO2, HfO2, Y2O3, L2O3 and their aluminates and silicates. The high k dielectric materials also comprise the above metal oxides including Ta2O5, TiO2, Al2O3, ZrO2, HfO2, Y2O3, L2O3 and nitrogen incorporated in their aluminates and silicates such as HfSiON. The high k dielectric material may comprise a single layer of one metal oxide or several layers including two or more metal oxides. Prior to the high k dielectric materials formation, an interfacial layer (IL) comprised of SiON, Si3N4 or SiO2 is formed between high k and the substrate. The IL layer could be formed by chemical oxidation of the substrate by ozone, or by oxygen plasma oxidation substrate, or by rapid thermally grown oxide (RPO). Prior to the IL formation, a pre-gate cleaning step which is suitable for high-k deposition can be inserted before the high k dielectric stack deposition. Such a cleaning step typically involves a hydrophilic or hydrophobic technique that is well known to those skilled in the art.

Preferably, the cap layer 18 is made of silicon oxide or silicon oxy-nitride, nitride or combined stack. Nevertheless, the cap layer 18 may be made of any other suitable material such as silicon carbide. It should be understood that, in some cases, the cap layer 18 is omitted.

As shown in FIG. 1, silicon nitride spacers 26 are formed on respective sidewalls of the gate structure 12. A thin liner (not shown) such as silicon dioxide liner may be provided between the silicon nitride spacer 26 and the gate structure 12. Typically, the liner is L-shaped and has a thickness of about 30-120 angstroms.

The method of forming the silicon nitride spacers 26 generally includes the steps of depositing a conformal silicon nitride layer (not shown) on the silicon oxide liner; dry etching back the silicon nitride layer to form the silicon nitride spacers on sidewalls of the gate structure 12. According to the preferred embodiment of this invention, the thickness of the silicon nitride space 26 is between 300-1000 angstroms. In other cases, the silicon nitride spacer 26 may be replaced with other suitable materials including, but not limited to, silicon oxy-nitride (SiON), oxide-nitride-oxide (ONO), nitride-oxide (NO) or silicon carbide (SiC).

Using the silicon nitride spacers 26 and the gate structure 12 as an implant mask, a conventional ion implantation process is carried out to dope species such as boron, boron compound, arsenic, antimony, germanium or phosphorous into the semiconductor substrate 10, thereby forming heavily doped implantation in source/drain regions 28 that are contiguous with the shallow junction source/drain extensions 22.

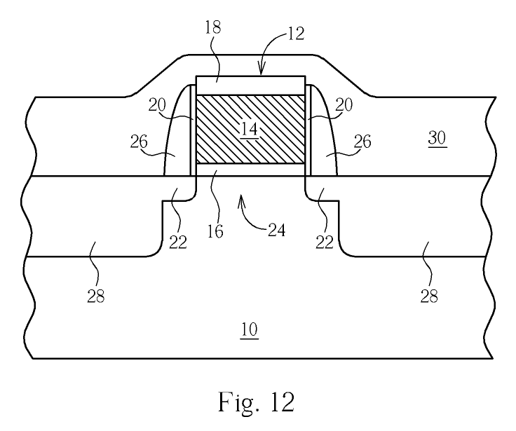

As shown in FIG. 12, after the source/drain implantation, a mask layer 30 is formed over the semiconductor substrate 10. The mask layer 30 may be spin-on glass (SOG), spin-on dielectric (SOD), wherein the mask layer 30 maybe silicon dioxide and silicon oxynitride formed by PECVD, LPCVD, SACVD or APCVD. Optionally, prior to the formation of the mask layer 30, a dielectric liner layer (not shown) including, but not limited to, silicon dioxide, silicon oxynitride, may be deposited over the semiconductor substrate 10. It is advantageous to add this dielectric liner layer because it is capable of blocking moisture.

The mask layer 30 includes, but not limited to, silicon dioxide, silicon oxynitride, spin-on polymers, spin-on photoresist materials, siloxene, polyimide (PI), benzocyclobutene (BCB), and low-k materials such as SiLK® (Trademark of Dow Chemical Company), Hydrogen Silisequioxane (HSQ) or Fox® (Trademark of Dow Corning). The mask layer 30 covers the gate structure 12, the silicon nitride spacers 26 and source/drain regions 28.

According to the preferred embodiment of this invention, the mask layer 30 is thinner at the top of the gate structure 12 than that at the top of the source/drain regions 28. Preferably, the thickness of the mask layer 30 that is directly above the gate structure 12 ranges between 500 angstroms and 50 angstroms. The thickness of the mask layer 30 above the source/drain regions 28 preferably ranges between 500 angstroms and 1500 angstroms.

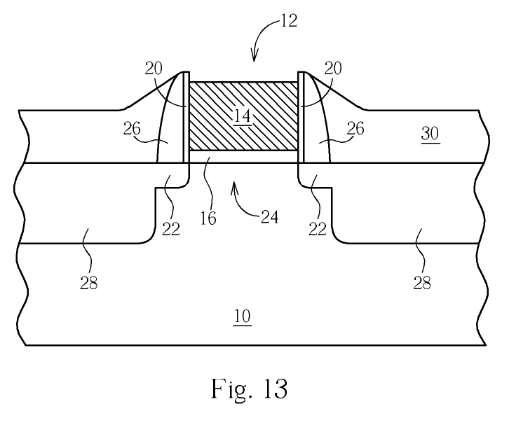

Subsequently, as shown in FIG. 13, the mask layer 30 and the cap layer 18 are removed to expose the gate electrode layer 14 of the gate structure 12. The mask layer 30 and the cap layer 18 may be removed by employing conventional wet etching methods or dry etching methods. Thereafter, the remaining thickness of the mask layer 30 above the source/drain regions 28 is preferably greater than 200 angstroms, more preferably, greater than 500 angstroms.

Another embodiment of this invention, the mask layer 30 is formed at the top of the gate structure 12 and at the top of the source/drain regions 28. The mask layer 30 are partially removed away to leave portion of the mask layer 30 on top of the gate electrode layer 14 and on top of the gate structure 12. The mask layer 30 may be partially removed by employing planarization method such as but not limited to CMP. It is noticed that herein the CMP process is quite difference from the prior art application. In this invention, the CMP is utilized to remove portion of the dielectric layer only and won't touch gate electrode layer. Subsequently, the mask layer 30 and the cap layer 18 may be removed by employing conventional wet etching methods or dry etching methods to expose the gate electrode layer 14 of the gate structure 12. After removing, the remaining thickness of the mask layer 30 above the source/drain regions 28 is preferably greater than 200 angstroms, more preferably, greater than 500 angstroms.

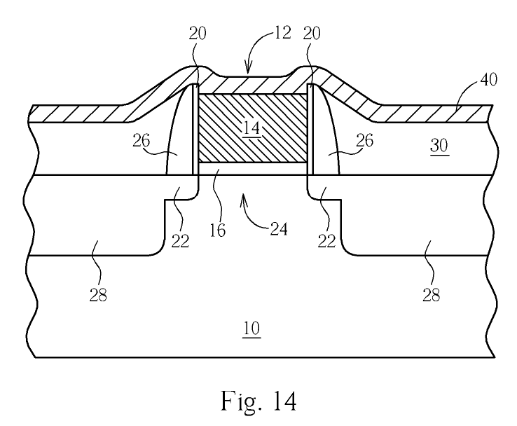

As shown in FIG. 14, a metal layer 40, such as nickel, cobalt or titanium, is blanket deposited over the semiconductor device including the exposed surface of the gate structure 12. The formation of metal layer 40 can be effected in any conventional manner, such as CVD or sputtering methods. An exemplary thickness of metal layer 40 is between about 80 angstroms and about 150 angstroms. However, for fully silicided gate application, the thickness of the metal is variable to the height of the gate electrode layer 14. The thickness of the deposited metal layer 40 is at least of a specific thickness that, during subsequent annealing, will react with the gate electrode layer 14, to partially silicide the gate electrode layer 14, wherein the silicided thickness on top of the unreacted gate 14a is greater than one half of the total thickness of the gate electrode layer 14.

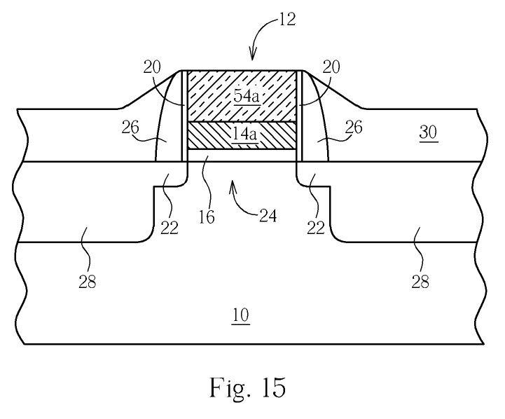

As shown in FIG. 15, a thermal annealing process is then carried out to partially silicide the gate electrode. The upper portion of the silicon layer 14 is transformed into a silicide layer 54a. The thermal annealing process may take place at a temperature of about 300° C. to about 900° C. for about 10 to about 600 seconds. Other parameters may be used depending on the metal used and the silicide qualities desired. Thereafter, the unreacted metal is removed. The unreacted metal may be removed by a wet chemical etch, such as with sulfuric peroxide mixture H₂SO₄:H₂O₂ (3:1) with deionized H₂O at a temperature of 100° C.

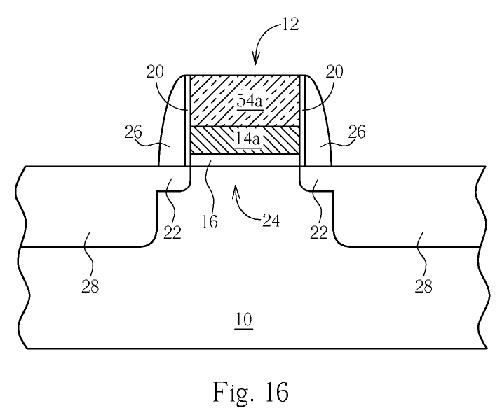

As shown in FIG. 16, after removing the unreacted metal, the mask layer 30 is removed from the semiconductor substrate 10 to expose the source/drain regions 28. The mask layer 30 may be removed by employing conventional wet etching methods or dry etching methods.

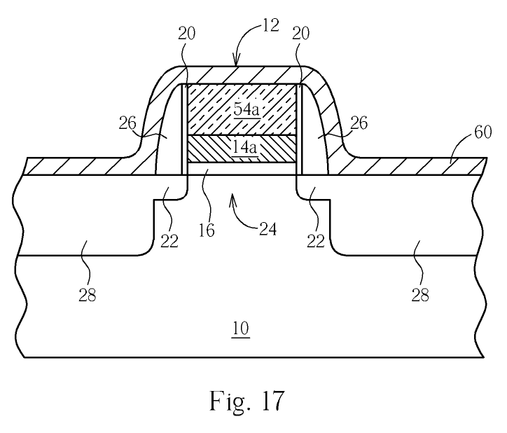

As shown in FIG. 17, another metal layer 60 is blanket deposited over the semiconductor substrate 10 including the exposed surface of the silicide layer 54a and the surface of the nitride spacers 26. The metal layer 60 also contacts the source/drain regions 28.

The metal layer 60 and the metal layer 40 may be of the same metal such as nickel, wherein thickness of the silicided source and drain is smaller than thickness of the silicided gate structure, and wherein the thickness of the silicided source and drain is smaller than 300 angstroms, preferably smaller than 200 angstroms. Alternatively, the metal layer 60 and the metal layer 40 may be composed of different metals, for example, the metal layer 60 is titanium or cobalt, while the metal layer 40 is nickel. The thickness of the deposited metal layer 60 is at least of a specific thickness that, during subsequent annealing, will react with the remaining gate electrode layer 14, to fully silicide the gate.

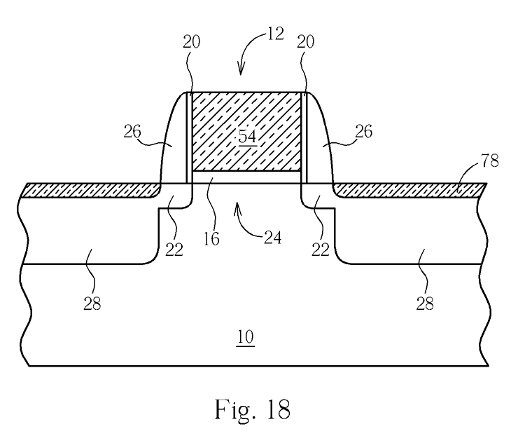

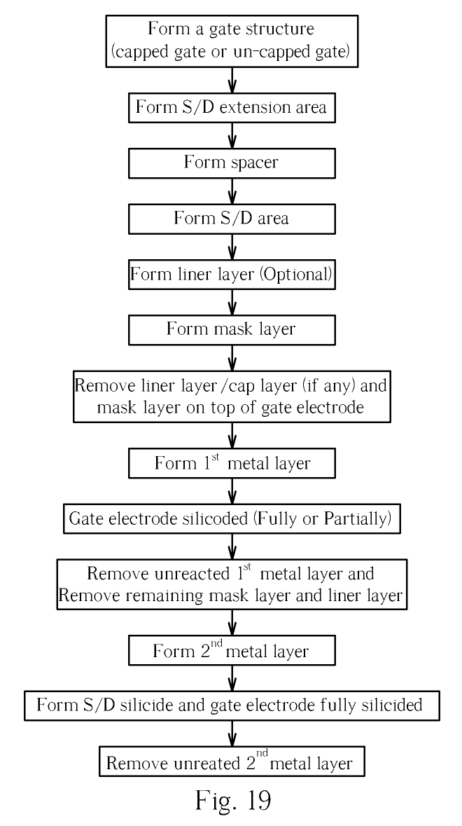

As shown in FIG. 18, another thermal annealing process is then carried out. The thermal annealing process may take place at a temperature of about 300° C. to about 900° C. for about 10 to about 300 seconds. Other parameters may be used depending on the metal used and the silicide qualities desired. Upon annealing, a silicide layer 78 forms in the source/drain regions 28. Simultaneously, the gate is fully silicidized to form a fully silicided layer 54. Thereafter, the unreacted metal is removed from the substrate 10. In some other embodiments, after removing the unreacted metal, a second thermal annealing process is carried out. The second thermal annealing process may be implemented at a temperature of about 300° C. to about 900° C. for about 10 to about 300 seconds. A summarized flow chart in accordance with this invention is illustrated in FIG. 19.

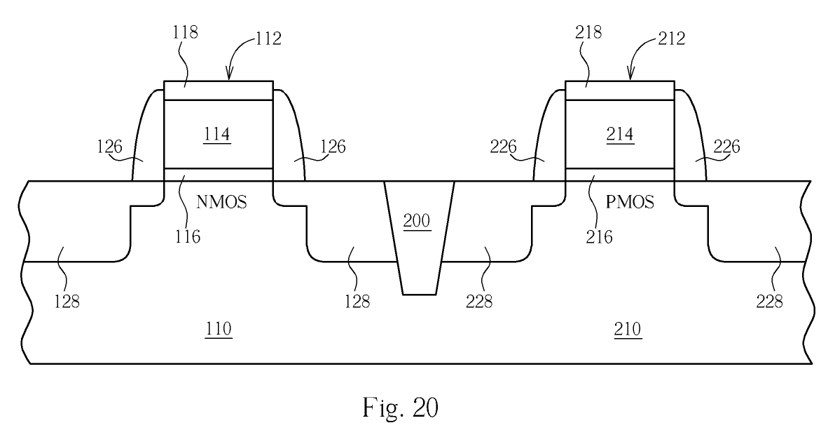

FIGS. 20-31 are schematic diagrams illustrating a dual-gate silicide process in accordance with another preferred embodiment of this invention. As shown in FIG. 20, an NMOS transistor 112 comprising a gate electrode 114 is formed on substrate 110 such as a P well substrate and a PMOS transistor 212 comprising a gate electrode 214 is formed on a substrate 210 such as an N well substrate. The NMOS transistor 112 further comprises a gate dielectric layer 116 between the gate electrode 114 and the substrate 110, a cap layer 118, sidewall spacers 126 and source/drain regions 128. Likewise, the PMOS transistor 212 further comprises a gate dielectric layer 216 between the gate electrode 214 and the substrate 210, a cap layer 218, sidewall spacers 226 and source/drain regions 228. A STI region 200 is provided to isolate the NMOS transistor 112 from the PMOS transistor 212.

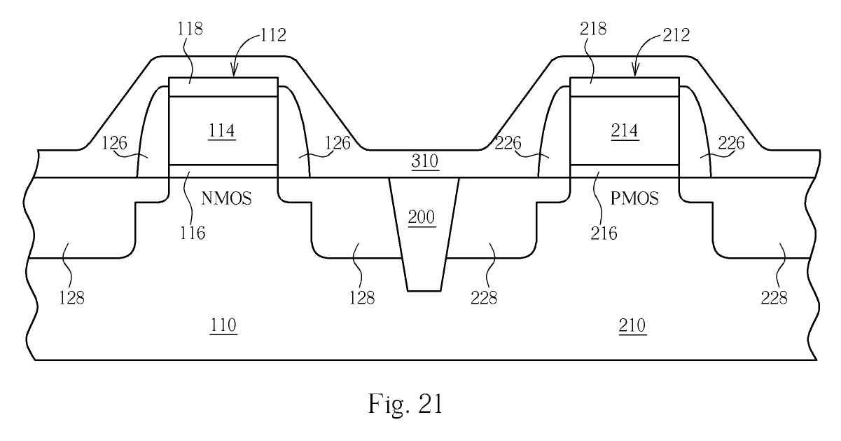

As shown in FIG. 21, a dielectric layer 310 is formed to cover the NMOS transistor 112 and the PMOS transistor 212. The dielectric layer 310 may be CVD dielectric layer or spin-on coating layers.

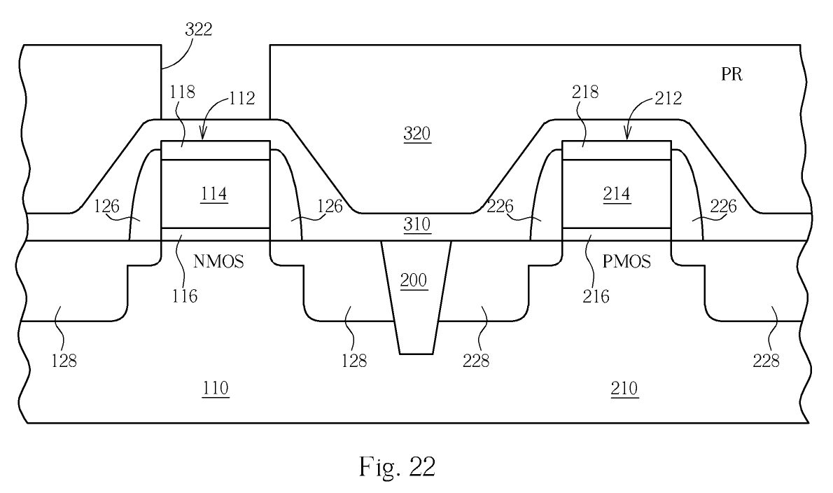

As shown in FIG. 22, a photoresist layer 320 is formed on the dielectric layer 310. A lithographic process is carried out to form an opening 322 in the photoresist layer 320. The opening 322 exposes a portion of the underlying dielectric layer 310 that covers the gate electrode 114 of the NMOS transistor 112. The opening 322 is directly above the gate electrode 114 of the NMOS transistor 112.

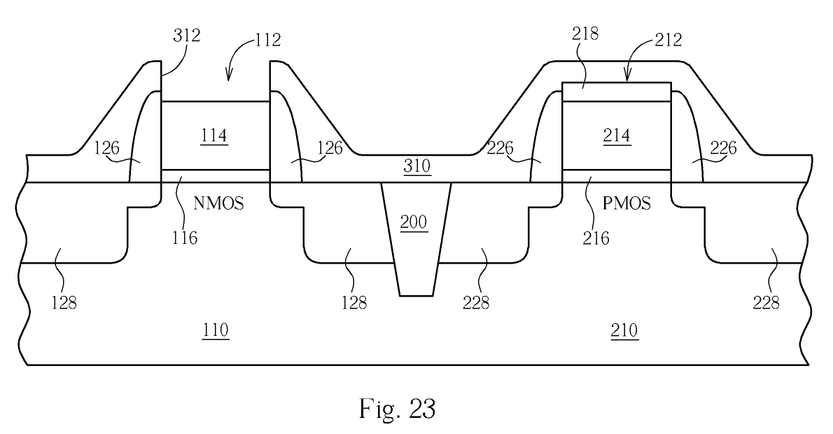

As shown in FIG. 23, a dry etching process is performed to etch away the exposed dielectric layer 310 and the cap layer 118 through the opening 322, thereby forming an opening 312 in the dielectric layer 310, wherein the opening 312 exposes the gate electrode 114.

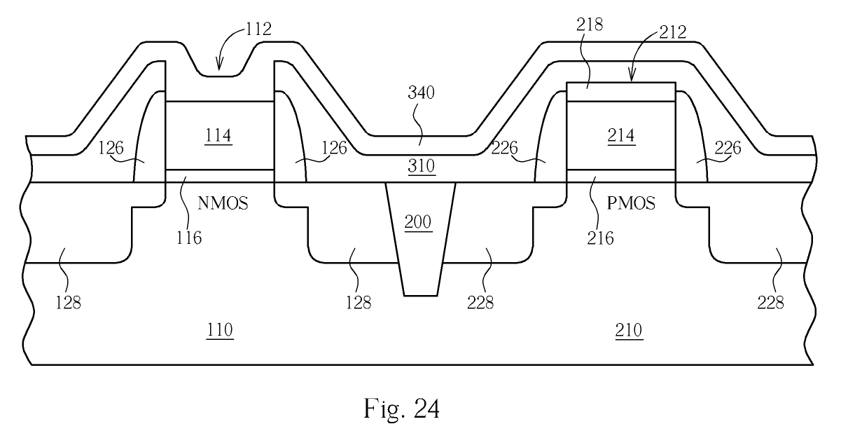

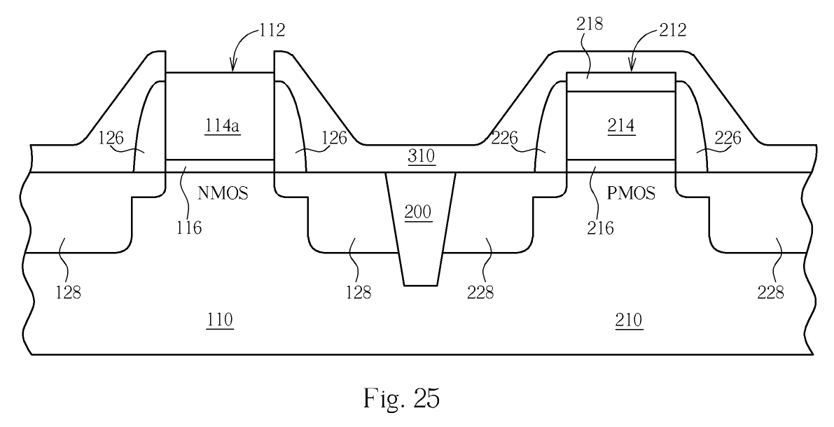

As shown in FIGS. 24 and 25, a nickel layer 340 having a thickness that is less than thickness of the gate electrode 114 is deposited or sputtered to cover the dielectric layer 310 and the opening 312. A thermal process is performed to transform the entire thickness of the gate electrode 114 into a first silicide gate 114a, preferably Si-rich phase comprising NiSi2 and NiSi. The temperature for forming the Si-rich phase 114a is larger than 500° C., preferably between 500-700° C. After the silicidation of the gate electrode 114, the unreacted nickel layer is removed.

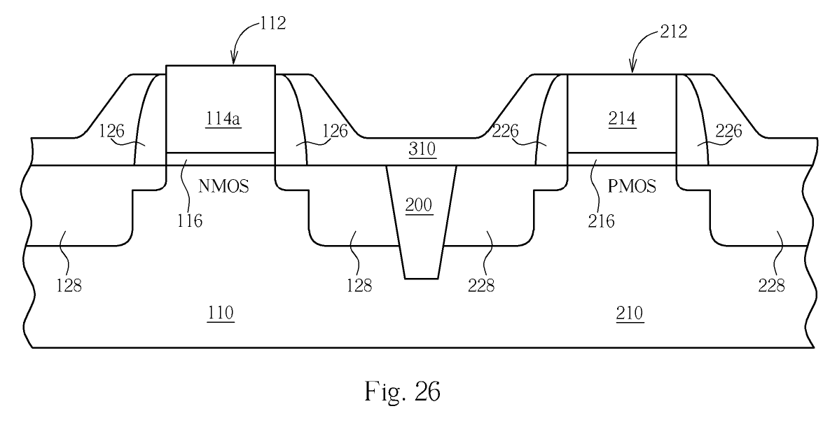

As shown in FIG. 26, the dielectric layer 310 is etched back. It is noted that if the dielectric layer 310 is CVD oxide, both a CMP process and etching back step may be used. The gate electrode 214 of the PMOS transistor 212 is exposed at this stage.

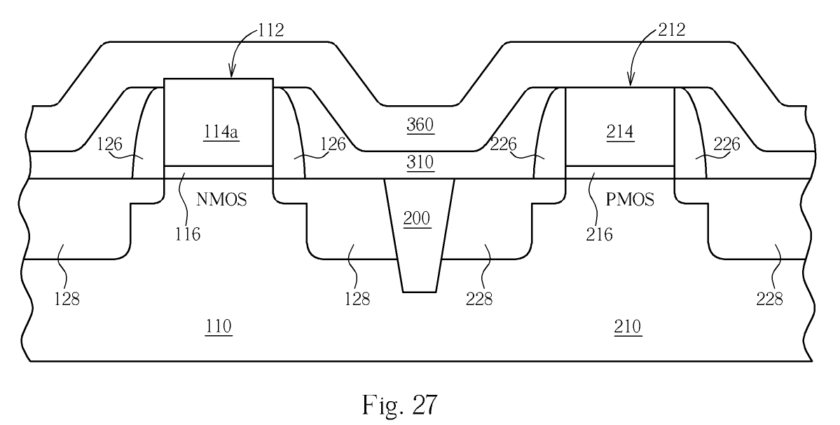

As shown in FIG. 27, a second nickel layer 360 having a thickness that is larger than thickness of the gate electrode 114 is deposited or sputtered to cover the remaining dielectric layer, the exposed top surface of the first silicide gate 114a and the exposed top surface of the gate electrode 214.

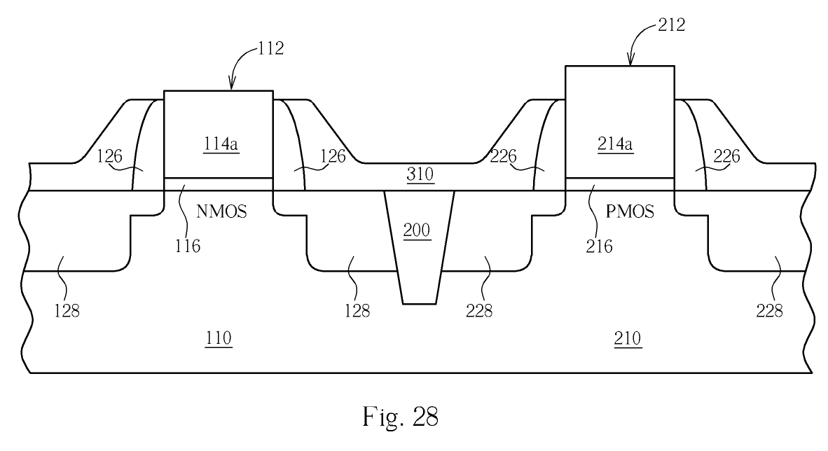

As shown in FIG. 28, a thermal process is performed to transform the entire thickness of the gate electrode 214 into a second silicide gate 214a, preferably Ni-rich phase comprising Ni3Si, Ni31Si12 and Ni2Si. The temperature for forming the Ni-rich phase 214a is less than 500° C., preferably between 350-500° C. Because the gate electrode 214 is transformed at substantially lower temperature such that the phase of the first silicide gate 114a will not be changed or affected. After the complete silicidation of the gate electrode 214, the unreacted nickel layer is removed.

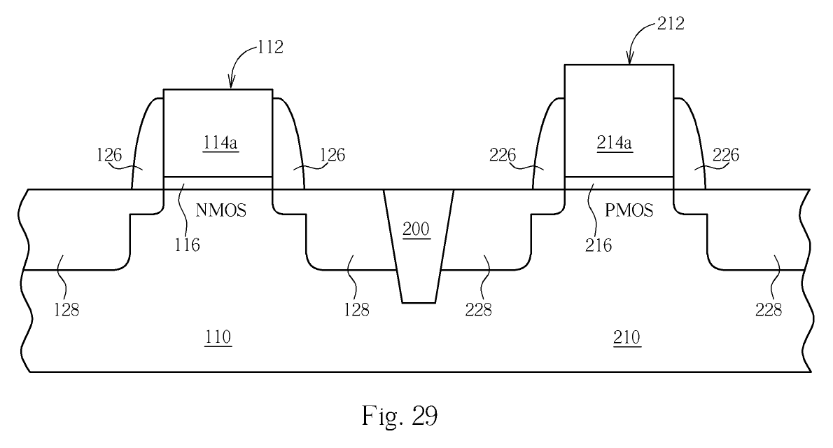

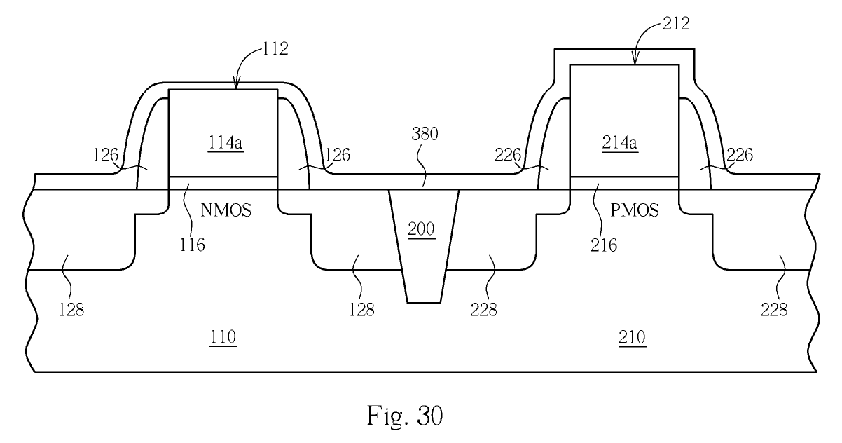

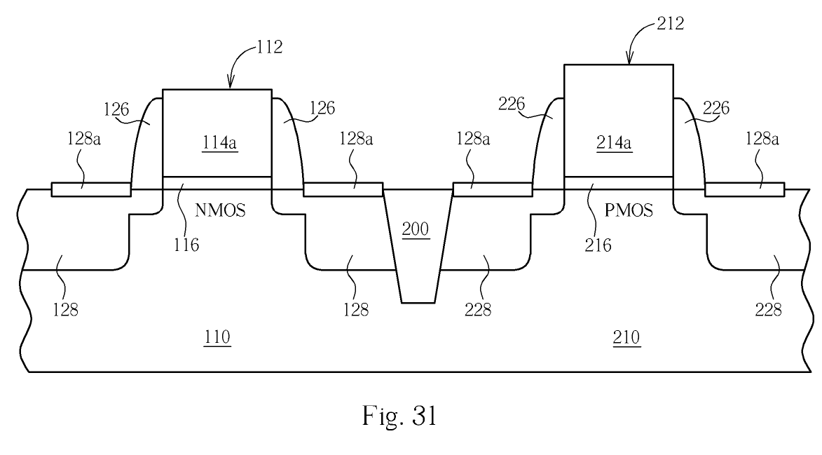

As shown in FIG. 29, the remaining dielectric layer 310 is removed. As shown in FIG. 30, a third nickel layer 380 is deposited or sputtered to cover the fully silicided NMOS transistor 112 and the fully silicided PMOS transistor 212. As shown in FIG. 31, a thermal process is performed to silicidize the surface of the source/drain regions 128 and 228.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming a fully silicided gate, comprising:
providing a gate structure of a transistor device on a substrate;
forming a mask layer covering the gate structure and source/drain regions of the transistor device;
removing an upper portion of the mask layer to merely expose a gate electrode layer of the gate structure;
fully siliciding the gate electrode layer of the gate structure;
removing the remaining mask layer from the substrate to expose the source/drain regions; and
siliciding the source/drain regions.

2. The method according to claim 1 wherein before forming the mask layer, the method further comprises the following steps:
using the gate structure as a hard mask, ion implanting the substrate to form a shallow junction source/drain extension beside the gate structure;
forming sidewall spacer on the gate structure; and
using the sidewall spacer and the gate structure as a hard mask, ion implanting the substrate to form the source/drain regions.

3. The method according to claim 2 wherein the sidewall spacer comprises silicon nitride.

4. The method according to claim 1 wherein before forming the mask layer, the method further comprises the following step:
forming a liner layer covering the gate structure and source/drain regions.

5. The method according to claim 4 wherein the liner layer comprises silicon dioxide and silicon oxy-nitride.

6. The method according to claim 1 wherein the gate structure comprises a gate dielectric layer between the gate electrode layer and the substrate, and wherein the gate dielectric layer comprises silicon oxide, silicon nitride, silicon oxy-nitride, and any combination thereof.

7. The method according to claim 6 wherein the gate dielectric layer is selected from a group of metal oxides comprising Ta2O5, TiO2, Al2O3, ZrO2, HfO2, Y2O3, L2O3 and their aluminates and silicates.

8. The method according to claim 1 wherein the gate electrode layer contains doped and un-doped impurities, and wherein the gate electrode layer comprises polycrystalline silicon and amorphous silicon.

9. The method according to claim 1 wherein the gate structure further comprises a cap layer on the gate electrode layer.

10. The method according to claim 9 wherein the cap layer comprises silicon oxide, silicon nitride, silicon oxy-nitride, silicon carbide, or any combination thereof.

11. The method according to claim 1 wherein the mask layer comprises spin-on glasses, spin-on polymers, spin-on photoresist materials, siloxene, polyimide (PI), benzocyclobutene (BCB), and spin-on low-k materials.

12. The method according to claim 11 wherein the spin-on low-k materials comprise SiLK®, Hydrogen Silisequioxane (HSQ) and FOx®.

13. The method according to claim 1 wherein the mask layer comprises silicon dioxide and silicon oxynitride.

14. The method according to claim 13 wherein the silicon dioxide and silicon oxynitride are formed by PECVD, LPCVD, SACVD and APCVD.

15. A method of forming a fully silicided gate, comprising:
providing a gate structure of a transistor device on a substrate;
forming a mask layer covering the gate structure and source/drain regions of the transistor device;
removing an upper portion of the mask layer to expose a gate electrode layer of the gate structure;
partially siliciding the gate electrode layer of the gate structure;
removing the remaining mask layer from the substrate to expose the source/drain regions; and
siliciding the source/drain regions and, simultaneously, fully siliciding the remaining gate electrode layer of the gate structure.

16. The method according to claim 15 wherein before spin-on coating the mask layer, the method further comprises the following steps:
using the gate structure as a hard mask, ion implanting the substrate to form a shallow junction source/drain extension next to the gate structure;
forming sidewall spacer on the gate structure; and
using the sidewall spacer and the gate structure as a hard mask, ion implanting the substrate to form the source/drain regions.

17. The method according to claim 16 wherein the sidewall spacer comprises silicon nitride.

18. The method according to claim 15 wherein before forming the mask layer, the method further comprises the following step:
forming a liner layer covering the gate structure and source/drain regions.

19. The method according to claim 18 wherein the liner layer comprises silicon dioxide and silicon oxy-nitride.

20. The method according to claim 15 wherein the gate structure comprises a gate dielectric layer between the gate electrode layer and the substrate.

21. The method according to claim 15 wherein the gate structure further comprises a cap layer on the gate electrode layer.

22. The method according to claim 21 wherein the cap layer comprises silicon oxide, silicon nitride, silicon oxy-nitride, silicon carbide or any combination thereof.

23. The method according to claim 15 wherein the mask layer comprises spin-on glasses, spin-on polymers, spin-on photoresist materials, siloxene, polyimide (PI), benzocyclobutene (BCB), and spin-on low-k materials.

24. The method according to claim 23 wherein the spin-on low-k materials comprise SiLK®, Hydrogen Silisequioxane (HSQ) and FOx®.

25. The method according to claim 15 wherein the mask layer comprises silicon dioxide and silicon oxynitride.

26. The method according to claim 25 wherein the silicon dioxide and silicon oxynitride are formed by PECVD, LPCVD, SACVD and APCVD.

27. A method for forming a semiconductor device, comprising:
providing a gate structure of a transistor device on a substrate;
forming a mask layer covering the gate structure and source/drain regions of the transistor device;
removing an upper portion of the mask layer to expose a gate electrode layer of the gate structure;
blanket depositing a first metal over the substrate;
siliciding the gate electrode layer of the gate structure by reacting with the first metal;
removing unreacted said first metal layer;
removing the remaining mask layer from the substrate to expose the source/drain regions;
blanket depositing a second metal over the substrate; and
siliciding the source/drain regions by reacting with the second metal.

28. The method according to claim 27 wherein before spin-on coating the mask layer, the method further comprises the following steps:
using the gate structure as a hard mask, ion implanting the substrate to form a shallow junction source/drain extension next to the gate structure;
forming sidewall spacer on the gate structure; and
using the sidewall spacer and the gate structure as a hard mask, ion implanting the substrate to form the source/drain regions.

29. The method according to claim 28 wherein the sidewall spacer comprises silicon nitride.

30. The method according to claim 27 wherein before spin-on coating the mask layer, the method further comprises the following step:
forming a liner layer covering the gate structure and source/drain regions.

31. The method according to claim 30 wherein the liner layer comprises CVD oxide and oxy-nitride.

32. The method according to claim 27 wherein the gate structure comprises a gate dielectric layer between the gate electrode layer and the substrate.

33. The method according to claim 27 wherein the gate structure further comprises a cap layer on the gate electrode layer.

34. The method according to claim 33 wherein the cap layer comprises silicon oxide, silicon nitride, silicon oxy-nitride, silicon carbide, or any combination thereof.

35. The method according to claim 27 wherein the mask layer comprises spin-on glasses, spin-on polymers, spin-on photoresist materials, siloxene, polyimide (PI), benzocyclobutene (BCB), and spin-on low-k materials.

36. The method according to claim 35 wherein the spin-on low-k materials comprise SiLK®, Hydrogen Silisequioxane (HSQ) and FOx®.

37. The method according to claim 27 wherein the first metal and the second metal are different metals.

38. The method according to claim 27 wherein the first metal and the second metal are made of the same metal, wherein thickness of the silicided source and drain is smaller than thickness of the silicided gate structure, and wherein said thickness of the silicided source and drain is smaller than 300 angstroms.

39. The method according to claim 27 wherein the first metal comprises nickel, cobalt and titanium.

40. The method according to claim 27 wherein the second metal comprises nickel, cobalt and titanium.

41. The method according to claim 27 wherein the removing upper portion of the mask layer comprises etching back and CMP.

42. The method according to claim 41 wherein the etching back comprises wet etching and dry etching process.

43. The method according to claim 42 wherein the dry etching gas comprises carbon, fluorine and their compounds.

44. The method according to claim 42 wherein the wet etching comprises HF and diluted HF.

45. A dual-gate silicide process, comprising:
providing a substrate having thereon a first gate structure, a second gate structure and source/drain regions;
forming a dielectric layer to cover the first gate structure, the second gate structure, and source/drain regions;
etching a first opening in the dielectric layer to expose a top surface of the first gate structure;
fully silicided the first gate structure into a first silicide gate;
etching a portion of the dielectric layer to expose a top surface of the second gate structure;
fully silicided the second gate structure into a second silicide gate;
removing remanent portion of the dielectric layer; and
siliciding the source/drain regions.

46. The dual-gate silicide process according to claim 45 wherein the first silicide gate is Si-rich phase gate formed at temperatures higher than 500° C.

47. The dual-gate silicide process according to claim 46 wherein the first silicide formation temperature is between 500-700° C.

48. The dual-gate silicide process according to claim 45 wherein the first silicide gate comprises NiSi2 and NiSi.

49. The dual-gate silicide process according to claim 45 wherein the second silicide gate is Ni-rich phase gate formed at temperatures lower than 500° C.

50. The dual-gate silicide process according to claim 49 wherein the second silicide formation temperature is between 350-500° C.

51. The dual-gate silicide process according to claim 45 wherein the second silicide gate comprises Ni3Si, Ni31Si12 and Ni2Si.

52. The dual-gate silicide process according to claim 45 wherein the formation temperature of the first silicide gate is substantially higher than second silicide gate.

53. A dual-gate silicide process, comprising:
providing a substrate having thereon a first gate structure, a second gate structure and at least one source/drain regions;
forming a dielectric layer to cover the first gate structure, second gate structure and source/drain regions;
etching a first opening in the dielectric layer to expose a top surface of the first gate structure;
depositing a first metal layer into the first opening and on the dielectric layer;
transforming the first gate structure into a first silicide gate;
removing unreacted portion of the first metal layer;
etching a portion of the dielectric layer to expose a top surface of the second gate structure;
depositing a second metal layer to cover the first silicide gate, the dielectric layer and the exposed top surface of the second gate structure;
transforming the second gate structure into a second silicide gate;
removing unreacted portion of the second metal layer;
removing remanent portion of the dielectric layer;
depositing a third metal over the substrate; and
siliciding the source/drain regions by reacting with the third metal.

54. The dual-gate silicide process according to claim 53 wherein the first silicide gate is the Si-rich phase gate at temperatures higher than 500° C.

55. The dual-gate silicide process according to claim 53 wherein the first silicide gate comprises NiSi2 and NiSi.

56. The dual-gate silicide process according to claim 53 wherein the second silicide gate is Ni-rich phase gate at temperatures lower than 500° C.

57. The dual-gate silicide process according to claim 53 wherein the second silicide gate comprises Ni3Si, Ni31Si12 and Ni2Si.

58. The dual-gate silicide process according to claim 53 wherein the formation temperature of the first silicide gate is substantially higher than second silicide gate.
